(19) United States
(12) Patent Application Publication
(10) Pub. No.: US 2025/0194295 A1
(43) Pub. Date: Jun. 12, 2025

(54) GaN LED HAVING MULTI-SERIES JUNCTION STRUCTURE AND IMPROVED LIGHT CHARACTERISTIC AND METHOD OF MANUFACTURING THE SAME

(71) Applicant: Korea Photonics Technology Institute, Gwangju (KR)

(72) Inventors: Jung Hong MIN, Pyeongtaek-si Gyeonggi-do (KR); Tae Hun JEONG, Gwangju (KR); Sung Hoon JUNG, Gwangju (KR); Sang Hern LEE, Gwangju (KR)

(73) Assignee: Korea Photonics Technology Institute, Gwangju (KR)

(21) Appl. No.: 19/057,116

(22) Filed: Feb. 19, 2025

Related U.S. Application Data
(63) Continuation of application No. PCT/KR2023/020153, filed on Dec. 8, 2023.

(30) Foreign Application Priority Data
Nov. 7, 2023 (KR) 10-2023-0152558

(51) Int. Cl. H10H 20/813; H10H 20/01; H10H 20/811; H10H 20/815; H10H 20/816; H10H 20/825; H10H 20/833; H10H 20/84

(52) U.S. Cl. CPC H10H 20/8131; H10H 20/0137; H10H 20/016; H10H 20/017; H10H 20/034; H10H 20/811; H10H 20/815; H10H 20/8162; H10H 20/825; H10H 20/833; H10H 20/84

(57) ABSTRACT

Disclosed are an LED having a multi-series junction structure and improved light characteristics and a method of manufacturing the same. An LED includes a substrate, a buffer layer deposited on the substrate, a first n type semiconductor layer, a first active layer, and a first p type semiconductor layer sequentially deposited on the buffer layer, a tunnel junction layer deposited on the p type semiconductor layer, a second n type semiconductor layer, a second active layer, and a second p type semiconductor layer sequentially deposited on the tunnel junction layer, ITO formed on the second p type semiconductor layer, and a passivation layer deposited on the side or front of the first n type semiconductor layer to the ITO. Etching is performed from the ITO to one location of the first n type semiconductor layer so that the ITO to the first n type semiconductor layer have a mesa structure.

### CROSS-REFERENCE TO RELATED APPLICATIONS

The present application is a continuation of International Application No. PCT/KR2023/020153, filed on Dec. 8, 2023 which claims priority under 35 U.S.C. § 119 (a) to Korean Patent Application No. 10-2023-0152558, filed in the Korean Intellectual Property Office on Nov. 7, 2023, the entire disclosure of which is incorporated herein by reference.

Furthermore, this patent is the results of research that was carried out with the support of the National.

Research Foundation of Korea by the finances of the government of the Republic of Korea (The Ministry of Science and ICT) in 2023 (a unique project number: 1711195422, a detailed project number: 2022M3H4A3A01082883, a project name: the development of an InGaN red LED source technology having an external quantum efficiency 30% breakthrough 5 μm class).

### BACKGROUND

### 1. Technical Field

The present disclosure relates to a gallium nitride (GaN) LED having a multi-series junction structure and improved light characteristics, such as brightness, light efficiency, or reliability, and a method of manufacturing the same.

### 2. Related Art

Contents described in this part merely provide background information of the present embodiment, and do not constitute a conventional technology.

A light-emitting diode (LED) is an inorganic light source and is variously used in several fields, such as display devices, lamps for a vehicle, and common lights. The LED rapidly substitutes the existing light source due to the advantages of a long lifespan, low consumption power, and a fast response speed.

In general, the LED may implement various colors by using mixed colors of blue, green, and red. The LED that is used in various devices includes a plurality of pixels in order to implement various images or colors. Each of the pixels includes blue, green, and red sub-pixels. The LED may determine the color of a specific pixel by using the colors of the sub-pixels, and may implement an image by a combination of the pixels.

Recently, a micro LED the length of one side of which is 100 μm or less is developed. The micro LED has been in the spotlight as a light-emitting element of a next-generation display because the micro LED has a fast response speed, low power, and high brightness compared to the existing LED.

However, if the size of the micro LED is gradually reduced as described above, there is a sidewall effect in which a leakage current is generated because a current flowing within the LED is driven to the outskirts of the current. Accordingly, there is a problem in that external quantum efficiency (EQE) of micro LEDs having a relatively small size is reduced.

### SUMMARY

An embodiment of the present disclosure is directed to providing a gallium nitride (GaN) LED having a vertically stacked structure and improved light characteristics, such as brightness, light efficiency, or reliability, and a method of manufacturing the same.

According to an aspect of the present disclosure, there is provided a light-emitting diode (LED), including a substrate, a buffer layer deposited on the substrate, a first n type semiconductor layer, a first active layer, and a first p type semiconductor layer sequentially deposited on the buffer layer, a tunnel junction layer deposited on the p type semiconductor layer, a second n type semiconductor layer, a second active layer, and a second p type semiconductor layer sequentially deposited on the tunnel junction layer, ITO formed on the second p type semiconductor layer, and a passivation layer deposited on the side or front of the first n type semiconductor layer to the ITO, wherein etching is performed from the ITO to one location of the first n type semiconductor layer so that the ITO to the first n type semiconductor layer have a mesa structure.

According to an aspect of the present disclosure, the first n type semiconductor layer, the second n type semiconductor layer, the first p type semiconductor layer, and the second p type semiconductor layer are each implemented with gallium nitride (GaN).

According to an aspect of the present disclosure, the LED further includes a super lattice layer deposited between the n type semiconductor layer and the active layer and configured to reduce stress.

According to an aspect of the present disclosure, the super lattice layer is implemented with InGaN/GaN.

According to an aspect of the present disclosure, the LED further includes a hole preservation layer deposited on the active layer and configured to preserve holes or block the introduction of electrons.

According to an aspect of the present disclosure, the hole preservation layer is implemented with InGaN doped with a p type dopant and preserves holes.

According to an aspect of the present disclosure, the hole preservation layer is implemented with AlInGaN doped with a p type dopant and blocks the introduction of electrons.

According to an aspect of the present disclosure, there is provided a method of manufacturing a light-emitting diode (LED), including a first deposition process of depositing a buffer layer on a substrate, a second deposition process of sequentially depositing a first n type semiconductor layer, a first active layer, and a first p type semiconductor layer on the buffer layer, a third deposition process of depositing a tunnel junction layer on the first p type semiconductor layer, a fourth deposition process of sequentially depositing a second n type semiconductor layer, a second active layer, and a second p type semiconductor layer on the tunnel junction layer, a forming process of forming ITO on the second p type semiconductor layer, an etching process of performing etching from the ITO to one location of the first n type semiconductor layer so that the ITO to the first n type semiconductor layer have a mesa structure, a fifth deposition process of depositing an etch stop layer and an ohmic layer on each of the first n type semiconductor layer and the ITO, and a sixth deposition process of depositing a passivation layer on a side or front of the first n type semiconductor layer to the ITO.

According to an aspect of the present disclosure, each of the layers etched by the etching process has a preset width.

According to an aspect of the present disclosure, the method further includes a progress process of performing annealing after the etching process is performed.

According to an aspect of the present disclosure, the tunnel junction layer or the p type semiconductor layer is activated by the progress process.

According to an aspect of the present disclosure, there is provided a light-emitting diode (LED) manufactured by the manufacturing method.

According to an aspect of the present disclosure, there is provided a light-emitting diode (LED), including a substrate, a buffer layer deposited on the substrate, a first n type semiconductor layer, a first active layer, and a first p type semiconductor layer sequentially deposited on the buffer layer, a first tunnel junction layer deposited on the p type semiconductor layer, a second n type semiconductor layer, a second active layer, and a second p type semiconductor layer sequentially deposited on the tunnel junction layer, a second tunnel junction layer and a third n type semiconductor layer sequentially deposited on the second p type semiconductor layer, and a passivation layer deposited on a side or front of the first n type semiconductor layer to the third n type semiconductor layer, wherein etching is performed from the third n type semiconductor layer to one location of the first n type semiconductor layer so that the third n type semiconductor layer to the first n type semiconductor layer have a mesa structure.

According to an aspect of the present disclosure, the first n type semiconductor layer, second n type semiconductor layer, the first p type semiconductor layer, and the second p type semiconductor layer are each implemented with gallium nitride (GaN).

According to an aspect of the present disclosure, there is provided a method of manufacturing a light-emitting diode (LED), including a first deposition process of depositing a buffer layer on a substrate, a second deposition process of sequentially depositing a first n type semiconductor layer, a first active layer, and a first p type semiconductor layer on the buffer layer, a third deposition process of depositing a tunnel junction layer on the first p type semiconductor layer, a fourth deposition process of sequentially depositing a second n type semiconductor layer, a second active layer, and a second p type semiconductor layer on the tunnel junction layer, a fifth deposition process of sequentially depositing a second tunnel junction layer and a third n type semiconductor layer on the second p type semiconductor layer, an etching process of performing etching from the third n type semiconductor layer to one location of the first n type semiconductor layer so that the third n type semiconductor layer to the first n type semiconductor layer have a mesa structure, a sixth deposition process of depositing an etch stop layer and an ohmic layer on each of the first n type semiconductor layer and the ITO, and a seventh deposition process of depositing a passivation layer on the side or front of the first n type semiconductor layer to the ITO.

According to an aspect of the present disclosure, there is provided the LED manufactured by the method.

As described above, an aspect of the present disclosure has an advantage of improved light characteristics, such as brightness, light efficiency, or reliability due to the vertically stacked structure.

### BRIEF DESCRIPTION OF THE DRAWINGS

FIG. 1 is a diagram illustrating a construction of a multi-series junction LED according to a first embodiment of the present disclosure.

FIG. 2 is a diagram illustrating a construction of a multi-series junction LED according to a second embodiment of the present disclosure.

FIGS. 3 to 6 are diagrams illustrating a process of manufacturing a multi-series junction LED according to an embodiment of the present disclosure.

FIGS. 7A, 7B, 8A, and 8B are diagrams illustrating a process of manufacturing a multi-series junction LED according to an embodiment of the present disclosure.

FIGS. 9 to 12 are diagrams illustrating a process of manufacturing a multi-series junction LED according to an embodiment of the present disclosure.

FIG. 13A is a illustrating graph electrical characteristics of the multi-series junction LED according to an embodiment of the present disclosure and a conventional LED.

FIG. 13B is a graph illustrating input power versus the intensity of output light of the multi-series junction LED according to an embodiment of the present disclosure and a conventional LED.

FIG. 14 is a flowchart illustrating a method of manufacturing the multi-series junction LED according to an embodiment of the present disclosure.

### DETAILED DESCRIPTION

The present disclosure may be changed in various ways and may have various embodiments. Specific embodiments are to be illustrated in the drawings and specifically described. It should be understood that the present disclosure is not intended to be limited to the specific embodiments, but includes all of changes, equivalents and/or substitutions included in the spirit and technical range of the present disclosure. Similar reference numerals are used for similar components while each drawing is described.

Terms, such as a first, a second, A, and B, may be used to describe various components, but the components should not be restricted by the terms. The terms are used to only distinguish one component from another component. For example, a first component may be referred to as a second component without departing from the scope of rights of the present disclosure. Likewise, a second component may be referred to as a first component. The term “and/or” includes a combination of a plurality of related and described items or any one of a plurality of related and described items.

When it is described that one component is “connected” or “coupled” to the other component, it should be understood that one component may be directly connected or coupled to the other component, but a third component may exist between the two components. In contrast, when it is described that one component is “directly connected to” or “directly coupled to” the other component, it should be understood that a third component does not exist between the two components.

Terms used in this application are used to only describe specific embodiments and are not intended to restrict the present disclosure. An expression of the singular number includes an expression of the plural number unless clearly defined otherwise in the context. In this specification, a term, such as “include” or “have”, is intended to designate the presence of a characteristic, a number, a step, an operation, a component, a part or a combination of them, and should be understood that it does not exclude the existence or possible addition of one or more other characteristics, numbers, steps, operations, components, parts, or combinations of them in advance.

All terms used herein, including technical terms or scientific terms, have the same meanings as those commonly understood by a person having ordinary knowledge in the art to which the present disclosure pertains, unless defined otherwise in the specification.

Terms, such as those defined in commonly used dictionaries, should be construed as having the same meanings as those in the context of a related technology, and are not construed as ideal or excessively formal meanings unless explicitly defined otherwise in the application.

Furthermore, each construction, process, procedure, or method included in each embodiment of the present disclosure may be shared within a range in which the constructions, processes, procedures, or methods do not contradict each other technically.

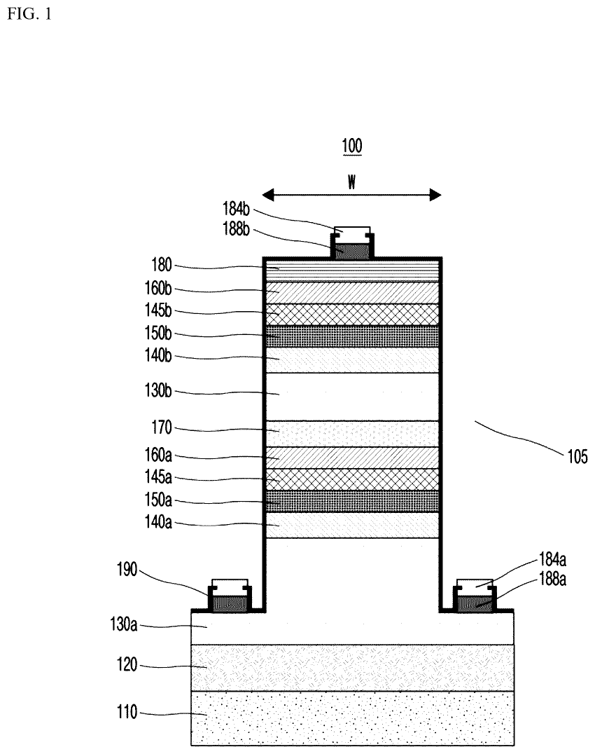

FIG. 1 is a diagram illustrating a construction of a multi-series junction LED according to a first embodiment of the present disclosure.

Referring to FIG. 1, a multi-series junction LED 100 (hereinafter abbreviated as an “LED”) according to the first embodiment of the present disclosure includes a substrate 110, a buffer layer 120, n type semiconductor layers 130a and 130b, super lattice layers 140a and 140b, hole preservation layers 145a and 145b, active layers 150a and 150b, a p type semiconductor layer 160, a tunnel junction layer 170, an ITO 180, electrode pads 184a and 184b, etch stop layers 188a and 188b, and a passivation layer 190.

A reduction of external quantum efficiency of the LED 100 attributable to a sidewall effect was minimized although the LED is implemented with a micro LED (a size of several tens or several hundreds of μm or less). The LED 100 can minimize a reduction of light characteristics (occurring due to a reduction of the size), such as brightness, light efficiency, or reliability, although the LED is implemented with a micro LED because the LED has a structure in which a plurality of LEDs that emits a single color is vertically stacked.

The substrate 110 provides a space in which the remaining components of the LED 100 can grow.

The buffer layer 120 is deposited on the substrate 110, and enables the n type semiconductor layer 130a to be grown on the top of the buffer layer.

The n type semiconductor layer 130a is deposited on the buffer layer 120, and may be implemented with GaN doped with an n type dopant (e.g., Si). So that the LED can fully output light having a visible wavelength band of a single color, the n type semiconductor layer 130a may be implemented with GaN (doped with the n type dopant).

As an electrode to be described later is implemented on the n type semiconductor layer 130a, the thickness of the n type semiconductor layer 130a is implemented to be relatively greater than the thickness of the n type semiconductor layer 130b. The n type semiconductor layer 130a may be implemented to have a thickness of 2 to 4 μm (in a height direction thereof).

The super lattice layer 140a is deposited on the n type semiconductor layer 130a, and enables the active layer 150a to be smoothly deposited on the top of the super lattice layer. The super lattice layer 140a is first deposited in order to reduce stress before the active layer 150a is deposited on the n type semiconductor layer 130a. The super lattice layer 140a may be implemented with InGaN/GaN so that the super lattice layer is deposited on the n type semiconductor layer 130a or the active layer 150a can be smoothly deposited.

The active layer 150a is deposited on the super lattice layer 140a, and generates light. The active layer 150a corresponds to a layer where holes generated from the p type semiconductor layer 160a and electrons generated from the n type semiconductor layer 130a are met and recombined. The electrons and holes are recombined in the active layer 150a, thus generating light. The active layer 150a may be implemented with a multi-quantum well (MQW), and has a structure in which a well layer (not illustrated) and a barrier layer (not illustrated) having different energy bands are alternately stacked once or more. The well layer (not illustrated) and barrier layer (not illustrated) of the active layer 150a may each be implemented with any one component, among GaN, InGaN, AlGaN, and AlInGaN. The active layer 150a may be implemented so that the well layer (not illustrated) has a lower band gap than the barrier layer (not illustrated).

The hole preservation layer 145a is deposited on the active layer 150a, and preserves holes or blocks the introduction of electrons. The hole preservation layer 145a may be implemented with InGaN doped with a p type dopant (e.g., Mg) and may preserve holes, or may be implemented with AlInGaN doped with a p type dopant and may block the introduction of electrons.

The p type semiconductor layer 160a is deposited on the hole preservation layer 145a, and may be implemented with GaN doped with a p type dopant. Likewise, the p type semiconductor layer 160a is implemented with GaN, and enables the LED to fully output light having a visible wavelength band of a single color.

The tunnel junction layer 170 is deposited on the p type semiconductor layer 160a and induces a tunneling phenomenon toward layers disposed on both sides of the tunnel junction layer so that an additional semiconductor layer and an additional active layer can be stacked. The tunnel junction layer 170 enables p⁺⁺-GaN and n⁺⁺-GaN layers to be sequentially deposited on the p type semiconductor layer 160a so that the n type semiconductor layer is deposited on the tunnel junction layer, and also enables the p type semiconductor layer 160a and the n type semiconductor layer 130b disposed at both ends of the tunnel junction layer to have an effect in which the p type semiconductor layer 160a and the n type semiconductor layer 130b are serially bonded. Each of the p⁺⁺-GaN and n⁺⁺-GaN layers within the tunnel junction layer 170 may be implemented to have a thickness of 5 to 10 nm (in a height direction thereof).

The n type semiconductor layer 130b, the super lattice layer 140b, the active layer 150b, the hole preservation layer 145b, and the p type semiconductor layer 160b are deposited on the tunnel junction layer 170 again, and thus the semiconductor layers 130a, 130b, 160a, and 160b and the active layers 150a and 150b are connected in series. Unlike the n type semiconductor layer 130a, the n type semiconductor layer 130b may be implemented to have a relatively thin thickness of 100 nm to 1.5 μm (in a height direction thereof) because an electrode does not need to be formed on the n type semiconductor layer.

The ITO 180 is formed on the p type semiconductor layer 160b, and enables power to be supplied to the p type semiconductor layer 160b.

The electrode pads 184a and 184b are implemented over the n type semiconductor layer 130a and the ITO 180, respectively, so that power can be supplied to the n type semiconductor layer 130a and the ITO 180.

The etch stop layers 188a and 188b are disposed at the bottoms of the electrode pads 184a and 184b, respectively, and prevent damage to the n type semiconductor layer 130a and the p type semiconductor layer 160b, respectively. Etching for opening the passivation layer 190 is performed so that he electrode pads 184a and 184b are disposed. In the etching process, there is a problem in that the n type semiconductor layer 130a and the p type semiconductor layer 160b are exposed to an etchant. The etch stop layers 188a and 188b are disposed at the bottoms of the electrode pads 184a and 184b, and prevent a problem in that the n type semiconductor layer 130a and the p type semiconductor layer 160b are exposed to the etchant. Furthermore, the etch stop layers 188a and 188b are implemented with preset metal (e.g., gold) and each have a color different from another layer. Accordingly, how well the etching has progressed can be checked when the etching for opening the passivation layer 190 is performed. Whether the etching for opening the passivation layer 190 has been sufficiently performed may be determined based on whether the etch stop layers 188a and 188b have been exposed (which may be easily checked based on whether the color of the etch stop layer has been exposed) in the etching process.

The LED 100 has a mesa structure 105 because etching is performed from the ITO 180 to a part of the n type semiconductor layer 130a (in a height direction thereof). As described above, the p type semiconductor layer 160 may be implemented with GaN doped with the p type dopant. In general, the doping of the p type dopant is performed by implanting magnesium (Mg) including a hydrogen (H) component. In this case, the H component included in magnesium (Mg) causes a problem in that the activity of magnesium (Mg) is limited. In order to prevent such a problem, conventionally, after GaN is doped with the p type dopant, the H component is made volatile by heating GaN. If the p type semiconductor layer has been deposited at the top of a device including the p type semiconductor layer, the p type semiconductor layer may sufficiently operate. However, if an additional layer is deposited on the p type semiconductor layer 160a as in the LED 100, the H component does not become easily volatile. Accordingly, there is a problem in that the p type-doped GaN is not activated.

In order to prevent such a problem, the LED 100 has the mesa structure 105 in which the ITO 180 to the n type semiconductor layer 130a have a preset width W (i.e., in a length direction perpendicular to a height direction thereof). As the layers of the LED are etched to have the mesa structure, the H component can easily become volatile in the process of doping the p type dopant. In this case, the preset width may be about 1 mm. If the width of each layer of the LED is greater than the preset width, the aforementioned problem may be caused because the H component disposed at the central part of the p type semiconductor layer is not discharged while becoming smoothly volatile. Accordingly, the layers 130a to 180 are etched to have the preset width.

The passivation layer 190 is deposited on the side of each etched layer, the sides of the etch stop layers 188a and 188b, the top layer, and ohmic layers 910a and 910b. The passivation layer 190 prevents each of the layers of the Led from being exposed to the outside.

The LED 100 can minimize the degradation of light characteristics, such as brightness, light efficiency, or reliability although the LED is implemented with a micro LED because the LED has the mesa structure.

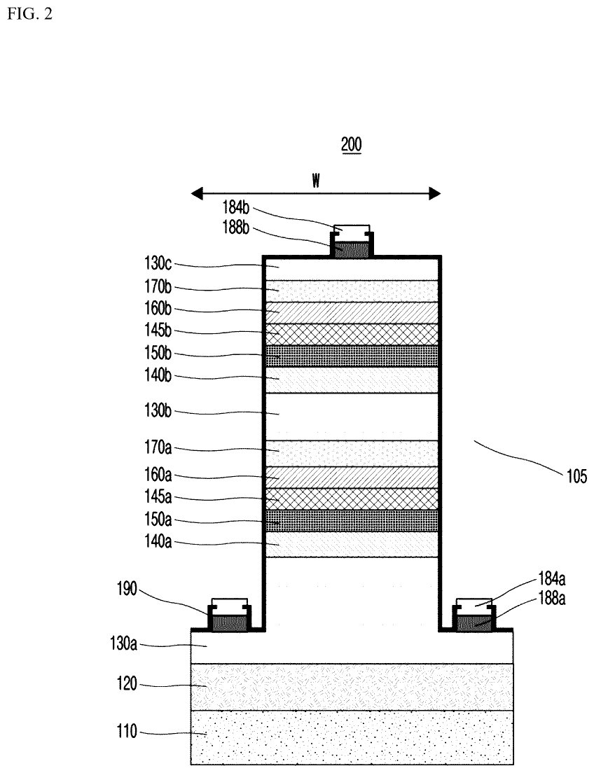

FIG. 2 is a diagram illustrating a construction of a multi-series junction LED according to a second embodiment of the present disclosure.

Referring to FIG. 2, a multi-series junction LED 200 (hereinafter abbreviated as an “LED”) according to the second embodiment of the present disclosure includes a tunnel junction layer 170b and an n type semiconductor layer 130c instead of the ITO 180 within the LED 100.

The tunnel junction layer 170b and the n type semiconductor layer 130c are deposited on the p type semiconductor layer 160b, and perform the same operation as the ITO 180. In this case, unlike the ITO 180, the tunnel junction layer 170b and the n type semiconductor layer 130c can be manufactured more easily because the tunnel junction layer 170b and the n type semiconductor layer 130c can be formed in the same process as the process of depositing each of the layers 120 to 160b on the substrate 110. Furthermore, the LED 200 may have relatively excellent light characteristics because the n type semiconductor layer 130c has a relatively higher light transmittance than the ITO 180.

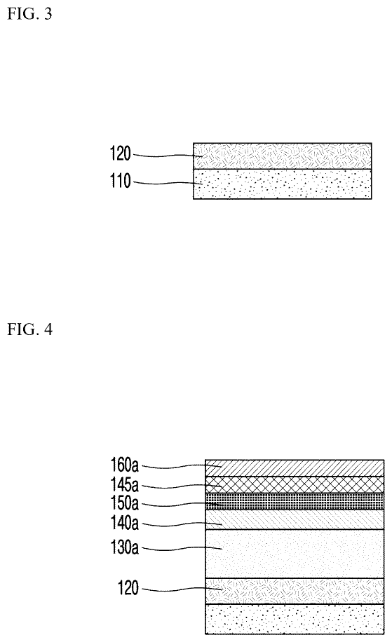

FIGS. 3 to 12 are diagrams illustrating a process of manufacturing a multi-series junction LED according to an embodiment of the present disclosure.

Referring to FIG. 3, the buffer layer 120 is deposited on the substrate 110.

Referring to FIG. 4, the n type semiconductor layer 130a, the super lattice layer 140a, the active layer 150a, the hole preservation layer 145a, and the p type semiconductor layer 160a are deposited on the buffer layer 120.

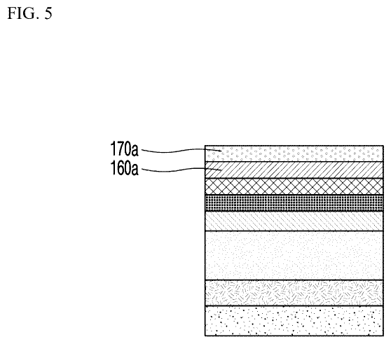

Referring to FIG. 5, the tunnel junction layer 170 or 170a is deposited on the p type semiconductor layer 160b.

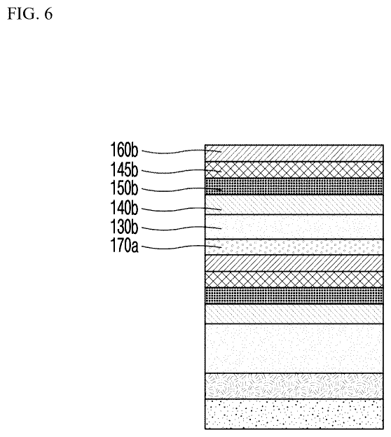

Referring to FIG. 6, the n type semiconductor layer 130b, the super lattice layer 140b, the active layer 150b, the hole preservation layer 145b, and the p type semiconductor layer 160b are deposited on the tunnel junction layer 170 or 170a.

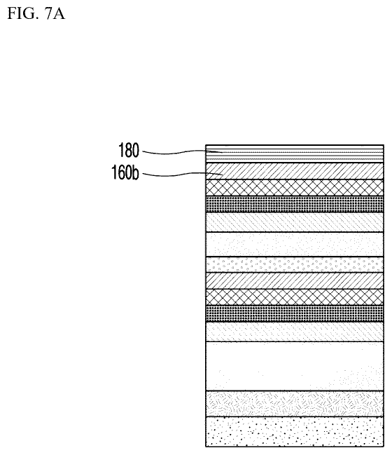

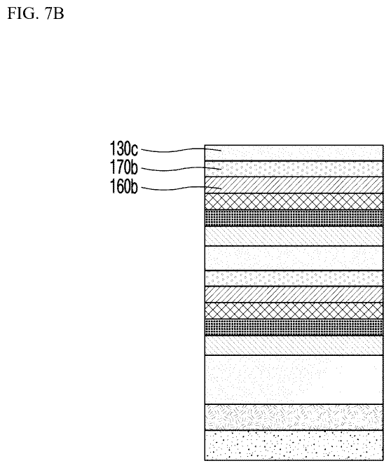

As illustrated in FIG. 7A, the ITO 180 is formed on the p type semiconductor layer 160b within the LED 100.

As illustrated in FIG. 7B, the tunnel junction layer 170b and the n type semiconductor layer 130c are deposited on the p type semiconductor layer 160b within the LED 200.

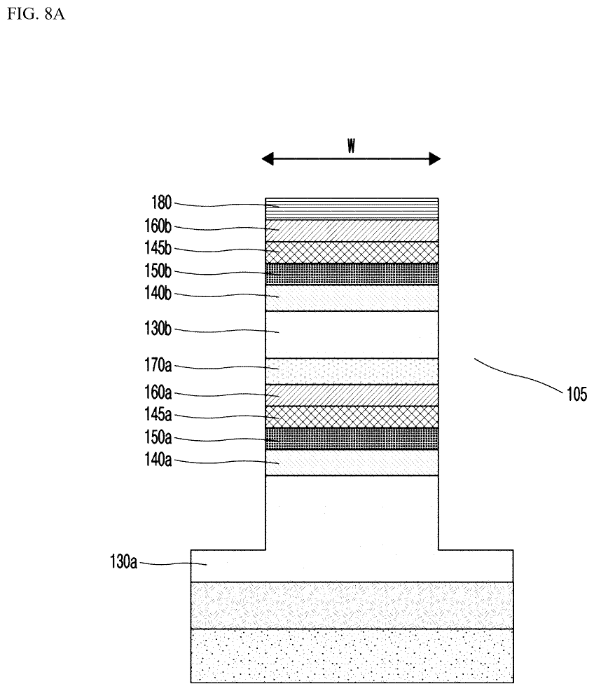

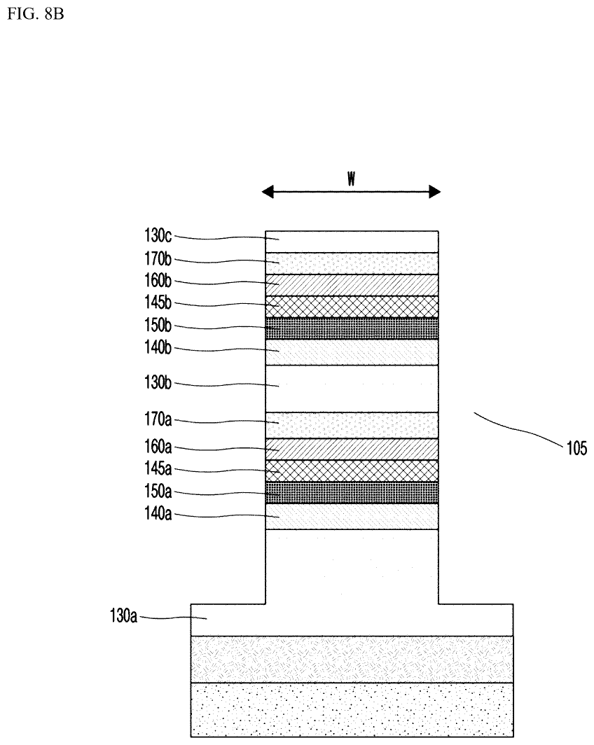

As illustrated in FIG. 8A, etching is performed from the ITO 180 to one location of the n type semiconductor layer 130a within the LED 100 in the height direction thereof so that the ITO 180 to the n type semiconductor layer 130a have the mesa structure 105. Each of the layers 130a to 180 has the preset width W.

As illustrated in FIG. 8B, etching is performed from the n type semiconductor layer 130c to one location of the n type semiconductor layer 130a within the LED 200 in the height direction thereof so that the n type semiconductor layer 130c to the n type semiconductor layer 130a have the mesa structure 105. Each of the layers 130a to 130c has the preset width W.

After all of the layers are etched to have the mesa structure, annealing is performed on the LED 100, 200 for the activation of the tunnel junction layer 170 and the activation of the p type semiconductor layer 160.

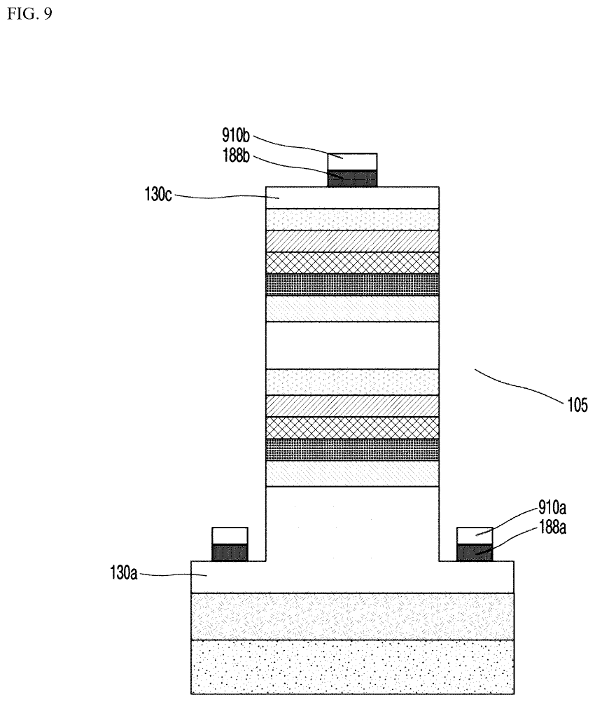

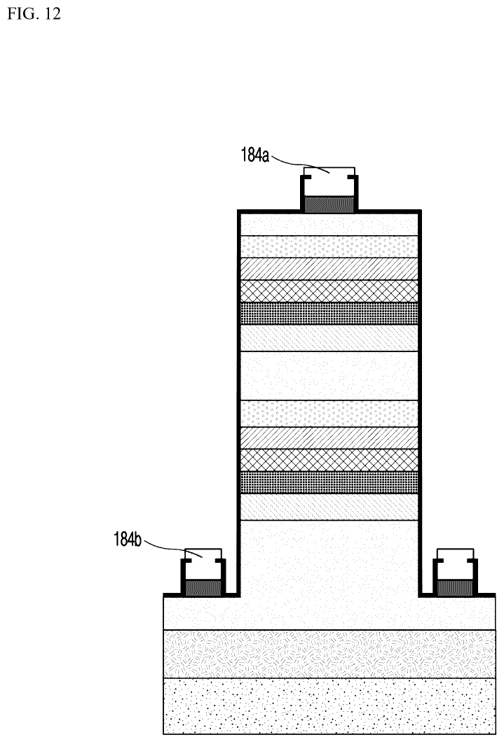

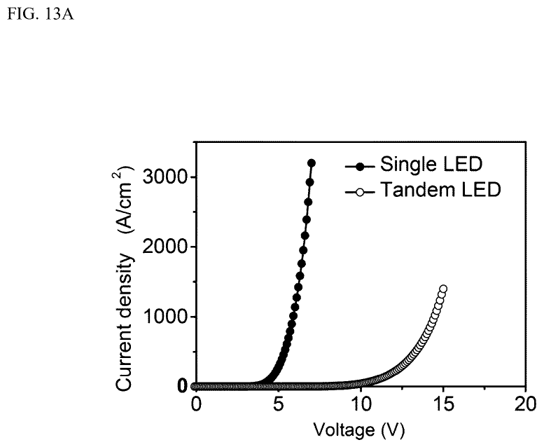

After the etching is performed, as illustrated in FIG. 9, the etch stop layers 188a and 188b and the ohmic layers 910a and 910b are deposited on the n type semiconductor layer 130a and the ITO 180 or the n type semiconductor layer 130a and the n type semiconductor layer 130c, respectively. The etch stop layers 188a and 188b are preferentially deposited on the n type semiconductor layer 130a and the ITO 180 or the n type semiconductor layer 130c, respectively. Thereafter, the ohmic layers 910a and 910b are deposited. Electrode pads 184a and 184b to be described with reference to FIG. 12 are disposed in the ohmic layers 910a and 910b, respectively, so that the n type semiconductor layer 130a and the ITO 180 or the n type semiconductor layer 130a and the n type semiconductor layer 130c may be subjected to an ohmic contact with each other.

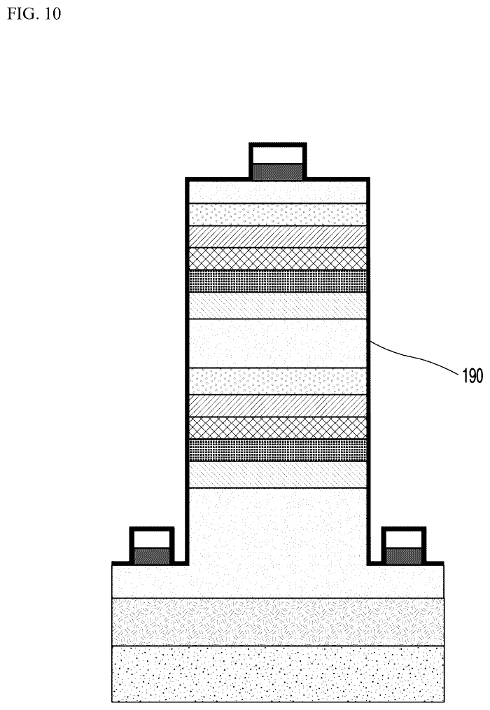

As illustrated in FIG. 10, the passivation layer 190 is deposited on the side of each etched layer, the sides of the etch stop layers 188a and 188b, the top layer, and the ohmic layers 910a and 910b.

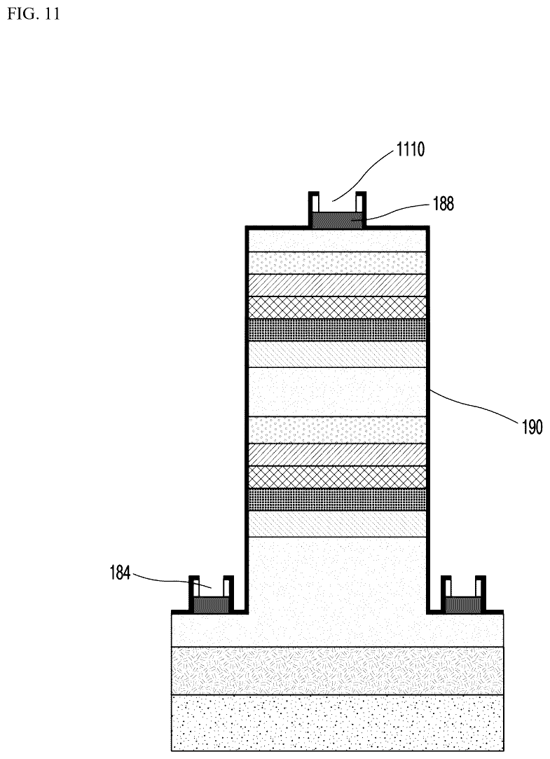

As illustrated in FIG. 11, etching is performed on locations 1110 where the etch stop layers 188a and 188b and the ohmic layers 910a and 910b are formed in the passivation layer 190. The etching is performed on parts of the passivation layer 190 and parts of the ohmic layers 910a and 910b, thus opening the passivation layer 190 because the etch stop layers 188a and 188b are formed.

Referring to FIG. 12, the electrode pads 184a and 184b are disposed in the locations where the passivation layer 190 has been opened. Since parts of the ohmic layers 910a and 910b remain, the electrode pads 184a and 184b may be subjected to ohmic contacts with the n type semiconductor layer 130a and the ITO 180 or the n type semiconductor layer 130a and the n type semiconductor layer 130c. Through such a process, the LED 100, 200 is manufactured.

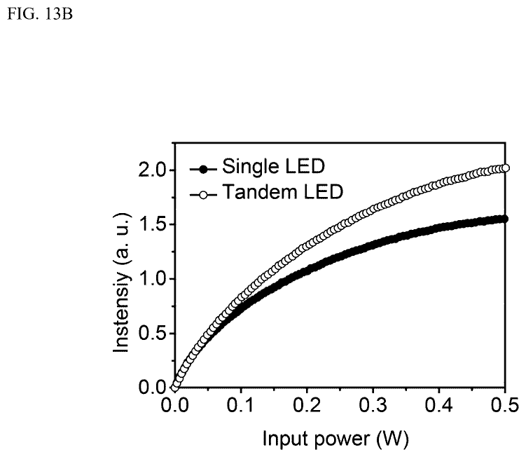

FIG. 13A is a graph illustrating electrical characteristics of the multi-series junction LED according to an embodiment of the present disclosure and a conventional LED.

From FIG. 13A, it may be seen that up to a relatively high voltage may be applied to the LED 100, 200 compared to the conventional LED. The meaning that high power can be applied to the LED means that a relatively low current may be applied to an LED having the same power. If an LED has the same amount of power although a low current is applied to the LED, this may mean that the LED has better light efficiency because the amount of heat that is generated as the LED operates is reduced. As illustrated in FIG. 13A, the LED 100, 200 may have a relatively excellent light efficiency because a relatively higher voltage can be applied to the LED compared to the conventional LED.

FIG. 13B is a graph illustrating input power versus the intensity of output light of the multi-series junction LED according to an embodiment of the present disclosure and a conventional LED.

From FIG. 13B, it may be seen that the LED 100, 200 can output light having a relatively strong intensity when the same power is applied to the Led compared to the conventional LED. In particular, it may be seen that if the amount of power more than 0.5 W is applied to the conventional LED, a margin of increase of the intensity of light that is output by the conventional LED is reduced. In contrast, it may be seen that although the amount of power more than 0.5 W is applied to the LED 100, 200, a margin of increase of the intensity of light that is output by the LED 100, 200 is not reduced.

It could be seen that the LED 100, 200 has relatively excellent light characteristics because the LED has the aforementioned structure.

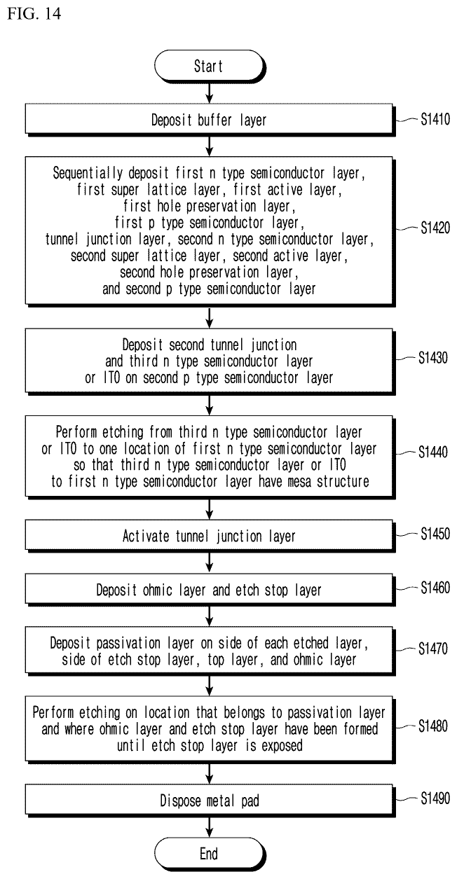

FIG. 14 is a flowchart illustrating a method of manufacturing the multi-series junction LED according to an embodiment of the present disclosure.

The buffer layer 120 is deposited on the substrate 110 (S1410).

The first n type semiconductor layer 130a, the first super lattice layer 140a, the first active layer 150a, the first hole preservation layer 145a, the first p type semiconductor layer 160a, the tunnel junction layer 170, the second n type semiconductor layer 130b, the second super lattice layer 140b, the second active layer 150b, the second hole preservation layer 145b, and the second p type semiconductor layer 160b are sequentially deposited on the buffer layer 120 (S1420).

The second tunnel junction 170b and the third n type semiconductor layer 130c or the ITO 180 are deposited on the second p type semiconductor layer 160b (S1430).

Etching is performed from the third n type semiconductor layer 130c or the ITO 180 to one location of the first n type semiconductor layer 130a so that the third n type semiconductor layer 130c or the ITO 180 to the first n type semiconductor layer 130a have the mesa structure (S1440).

The tunnel junction layer 170 is activated by performing an annealing process (S1450). The tunnel junction layer 170 is activated and the p type semiconductor layer 160 is activated by performing an annealing process.

The ohmic layers 910a and 910b and the etch stop layers 188a and 188b are deposited (S1460). The ohmic layers 910a and 910b and the etch stop layers 188a and 188b are deposited on the n type semiconductor layer 130a and the ITO 180 or the n type semiconductor layer 130a and the n type semiconductor layer 130c.

The passivation layer 190 is deposited on the side of each etched layer, the sides of the etch stop layers 188a and 188b, the top layer, and the ohmic layers 910a and 910b (S1470).

Etching is performed until the etch stop layers 188a and 188b are exposed at the position where the ohmic layers 910a and 910b and the etch stop layers 188a and 188b are formed in the passivation layer 190.

The metal pads 184a and 184b are disposed in the locations on which the etching has been performed (S1490).

The processes in FIG. 14 have been described as being sequentially executed, but this merely illustrates the technology spirit of an embodiment of the present disclosure. In other words, a person having ordinary knowledge in the art to which an embodiment of the present disclosure pertains may variously modify and change the processes by changing and executing the sequence described in FIG. 14 or executing one or more of the processes in parallel within a range that does not deviate from the intrinsic characteristic of an embodiment of the present disclosure. Accordingly, the processes in FIG. 14 are not limited to the time-series sequence.

The processes illustrated in FIG. 14 may be implemented in a computer-readable recording medium in the form of a computer-readable code. The computer-readable recording medium includes all types of recording devices in which data readable by a computer system is stored. That is, the computer-readable recording medium includes storage media, such as magnetic storage media (e.g., ROM, a floppy disk, and a hard disk) and optical reading media (e.g., CD-ROM and a DVD). Furthermore, the computer-readable recording medium may be distributed to computer systems connected over a network, and the computer-readable code may be stored and executed in a distributed manner.

The above description is merely a description of the technical spirit of the present embodiment, and those skilled in the art may change and modify the present embodiment in various ways without departing from the essential characteristic of the present embodiment. Accordingly, the embodiments should not be construed as limiting the technical spirit of the present embodiment, but should be construed as describing the technical spirit of the present embodiment.

The technical spirit of the present embodiment is not restricted by the embodiments. The range of protection of the present embodiment should be construed based on the following claims, and all of technical spirits within an equivalent range of the present embodiment should be construed as being included in the scope of rights of the present embodiment.

What is claimed is:

1. A light-emitting diode (LED) comprising:
a substrate;
a buffer layer deposited on the substrate;
a first n type semiconductor layer, a first active layer, and a first p type semiconductor layer sequentially deposited on the buffer layer;
a tunnel junction layer deposited on the p type semiconductor layer;
a second n type semiconductor layer, a second active layer, and a second p type semiconductor layer sequentially deposited on the tunnel junction layer;
ITO formed on the second p type semiconductor layer; and
a passivation layer deposited on a side or front of the first n type semiconductor layer to the ITO,
wherein etching is performed from the ITO to one location of the first n type semiconductor layer so that the ITO to the first n type semiconductor layer have a mesa structure.

2. The LED of claim 1, wherein the first n type semiconductor layer, the second n type semiconductor layer, the first p type semiconductor layer, and the second p type semiconductor layer are each implemented with gallium nitride (GaN).

3. The LED of claim 1, further comprising a super lattice layer deposited between the n type semiconductor layer and the active layer and configured to reduce stress.

4. The LED of claim 3, wherein the super lattice layer is implemented with InGaN/GaN.

5. The LED of claim 1, further comprising a hole preservation layer deposited on the active layer and configured to preserve holes or block an introduction of electrons.

6. The LED of claim 5, wherein the hole preservation layer is implemented with InGaN doped with a p type dopant and preserves holes.

7. The LED of claim 5, wherein the hole preservation layer is implemented with AlInGaN doped with a p type dopant and blocks an introduction of electrons.

8. A method of manufacturing a light-emitting diode (LED), comprising:
a first deposition process of depositing a buffer layer on a substrate;
a second deposition process of sequentially depositing a first n type semiconductor layer, a first active layer, and a first p type semiconductor layer on the buffer layer;
a third deposition process of depositing a tunnel junction layer on the first p type semiconductor layer;
a fourth deposition process of sequentially depositing a second n type semiconductor layer, a second active layer, and a second p type semiconductor layer on the tunnel junction layer;
a forming process of forming ITO on the second p type semiconductor layer;
an etching process of performing etching from the ITO to one location of the first n type semiconductor layer so that the ITO to the first n type semiconductor layer have a mesa structure;
a fifth deposition process of depositing an etch stop layer and an ohmic layer on each of the first n type semiconductor layer and the ITO; and
a sixth deposition process of depositing a passivation layer on a side or front of the first n type semiconductor layer to the ITO.

9. The method of claim 8, wherein each of the layers etched by the etching process has a preset width.

10. The method of claim 8, further comprising a progress process of performing annealing after the etching process is performed.

11. The method of claim 10, wherein the tunnel junction layer or the p type semiconductor layer are activated by the progress process.

12. A light-emitting diode (LED) comprising:
a substrate;
a buffer layer deposited on the substrate;
a first n type semiconductor layer, a first active layer, and a first p type semiconductor layer sequentially deposited on the buffer layer;
a first tunnel junction layer deposited on the p type semiconductor layer;
a second n type semiconductor layer, a second active layer, and a second p type semiconductor layer sequentially deposited on the tunnel junction layer;
a second tunnel junction layer and a third n type semiconductor layer sequentially deposited on the second p type semiconductor layer; and
a passivation layer deposited on a side or front of the first n type semiconductor layer to the third n type semiconductor layer,
wherein etching is performed from the third n type semiconductor layer to one location of the first n type semiconductor layer so that the third n type semiconductor layer to the first n type semiconductor layer have a mesa structure.

13. The LED of claim 12, wherein the first n type semiconductor layer, the second n type semiconductor layer, the first p type semiconductor layer, and the second p type semiconductor layer are each implemented with gallium nitride (GaN).
